(19) United States
(12) Patent Application Publication
(10) Pub. No.: US 2004/0039975 A1
(43) Pub. Date: Feb. 26, 2004

(54) Slowing graphics system for application optimization

(76) Inventors: Kirill Kounik, Tel Aviv (IL); Dov Zandman, Rosh-Haayin (IL)

Correspondence Address: MEYERTONS, HOOD, KIVLIN, KOWERT & GOETZEL, P.C., P.O. BOX 398, AUSTIN, TX, 78767-0398, US

(21) Appl. No.: 10/420,971

(22) Filed: Apr. 22, 2003

Related U.S. Application Data
(60) Provisional application No. 60/375,147, filed on Apr. 22, 2002.

(51) Int. Cl. G06F 11/00; G01R 31/28

(52) U.S. Cl. 714/741

(57) ABSTRACT

An emulation tool is provided, which approximates speed conditions of a MIDlet executing on a target device by matching graphical and computational operations of a development platform to the lesser performance capabilities of the target device. In one variant, the time required to perform primitive graphics operations is increased sufficiently to permit an application developer for the target device to observe graphics operations individually. In another variant optimization of graphic operations during the emulation is accomplished by slowing graphical display operations on the emulation platform by varying its refresh rate.

### CROSS-REFERENCE TO RELATED APPLICATIONS

This application claims the benefit of Provisional Application No. 60/375,147 filed Apr. 22, 2002. This application is related to Application No. ______ (STC File No. 45700), entitled “Slowing Network Connection for Application Optimization”, filed on even date.

### REFERENCE TO COMPUTER PROGRAM LISTING APPENDIX

A computer program listing appendix is submitted herewith on one compact disc and one duplicate compact disc. The total number of compact discs including duplicates is two. The file on the compact discs is software object code for carrying out the invention.

The name, date of creation, directory location, and size in bytes of the file on the compact disc are: “j2me_wireless_toolkit-1_{—}0_{—}4-hex-win.txt” of Apr. 14, 2002, located in the directory appendix and of length 25,042,094 bytes.

The file j2me_wireless_toolkit-1_{—}0_{—}4-hex-win.txt is a text file in ASCII encoding, which can be converted to binary format. If converted to binary format it can be installed on a Microsoft Windows™ system.

The material on the compact discs is incorporated by reference herein.

### BACKGROUND OF THE INVENTION

1. Field of the Invention

This invention relates to computer graphics. More particularly, this invention relates to emulation, testing and optimization of graphic-intensive applications in which there is disparity between the graphics performance of a development environment and a target device.

2. Description of the Related Art

The meanings of acronyms and certain terminology used herein are given in Table 1. The terms Sun, Sun Microsystems, the Sun logo, Java, and J2ME are trademarks or registered trademarks of Sun Microsystems, Inc., in the United States of America and other countries. All other company and product names may be trademarks of their respective companies.

TABLE 1

| | |
|---|---|
| API | Application Programming Interface |
| CLDC | Connected Limited Device Configuration |
| J2ME | Java 2 Micro Edition |
| MIDP | Mobile Information Device Profile |
| ROM | Read-only Memory |

The Mobile Information Device Profile (MTDP) defines a set of Java application programming interfaces (API's) that provide an application runtime environment for mobile information devices, such as cellular telephones. MIDP is defined in the document Mobile Information Device Profile (JSR-37), JCP Specification, Java 2 Platform, Micro Edition, 1.0a (Sun Microsystems Inc., Palo Alto, Calif., December, 2000), which is incorporated herein by reference. MIDP builds on the Connected Limited Device Configuration (CLDC) of the Java 2 Platform, Micro Edition (J2ME). MIDP applications that use the MIDP and CLDC API's are known as MIDlets.

The use of mobile and portable wireless devices has expanded dramatically in recent years. Many such devices having varying functions, internal resources, and capabilities now exist, including, but not limited to mobile telephones, personal digital assistants, medical and laboratory instrumentation, smart cards, and set-top boxes. All such devices are collectively referred to herein as mobile information devices or target devices. They tend to be special purpose, limited-function devices, rather than the general-purpose computing machines that have been previously known. Many of these devices are connected to the Internet, and are used for a variety of applications, such as banking and financial transactions, ticketing applications, wireless collaboration, and interactive games, and can be operated and even remotely in data networks. Mobile information devices typically have a very small memory, low-speed graphics, and slow communications performance, when compared with personal computers. While programmers commonly develop applications using personal computers as development platforms, the memory and speed limitations of the target mobile information devices must be taken into account in order for the applications to run satisfactorily on the target devices. In particular, the ability of mobile information devices to perform computations for purpose of rendering a graphics display, or to accept data in their graphic display modules is often a limiting factor in program development.

Graphics applications, even when running on high-end devices, may require optimization, in order that the graphics can be observed in slow motion, or in small groups of frames. Optimization of such graphics is addressed by the present invention.

### SUMMARY OF THE INVENTION

In accordance with a disclosed embodiment of the invention, a developer is provided with an emulation tool, which approximates speed conditions of an application, for example a MIDlet executing on a mobile information device, by matching graphical operations of a development platform to the lesser performance capabilities of the target device.

According to one disclosed embodiment of the invention, the time required to perform primitive graphics operations is increased sufficiently to permit an application developer for a target device to observe graphics operations individually.

In accordance with a disclosed embodiment of the invention testing and optimization of graphic operations to be performed by a target device having limited graphics capabilities is enabled by slowing graphical display operations on a development platform.

The invention provides a method of testing a computing application for a computing device, which is carried out by executing the application on a workstation by an emulation of the computing device. Execution of the application is performed by invoking a graphic primitive function on the workstation at least one time, and delaying execution of the graphic primitive function by a selected delay interval prior to each invocation of a graphic primitive function.

An aspect of the method includes determining whether the emulation satisfied a predetermined testing criterion, and responsively to the determination, adjusting the delay interval.

A further aspect of the method includes disabling double buffering of the workstation while executing the application.

The invention provides a method of testing a computing application for a computing device, which is carried out by modifying a state of double-buffering on a display of a workstation for graphic data to be presented on the display, setting a refresh rate of the display to a predefined value, and thereafter executing the application on the workstation by an emulation of the computing device.

In a further aspect of the method, the state of double-buffering is modified by enabling double-buffering.

Yet another aspect of the method includes determining whether the emulation satisfied a predetermined testing criterion, and responsively to the determination, adjusting the refresh rate to a new value.

The invention provides a computer software product, including a computer-readable medium in which computer program instructions are stored, which instructions, when read by a computer, cause the computer to perform a method of testing a computing application for a computing device, which is carried out by executing the application on the computer by an emulation of the computing device. Execution of the application is performed by invoking a graphic primitive function on the computer at least one time, and delaying execution of the graphic primitive function by a selected delay interval prior to each invocation of a graphic primitive function.

In an additional aspect of the computer software product, the computer is further instructed to carry out the steps of determining whether the emulation satisfied a predetermined testing criterion, and responsively to the determination, adjusting the delay interval.

In still another aspect of the computer software product, the computer is further instructed to disable double buffering of the computer while executing the application.

The invention provides a computer software product, including a computer-readable medium in which computer program instructions are stored, which instructions, when read by a computer, cause the computer to perform a method of testing a computing application for a computing device, which is carried out by modifying a state of double-buffering of graphic data to be presented on a display of the computer, setting a refresh rate of the display to a predefined value, and thereafter executing the application on the computer by an emulation of the computing device.

In yet another aspect of the computer software product, the state of double-buffering is modified by enabling double-buffering.

The invention provides a development system for testing a computing application for a computing device, including a display, and a workstation adapted to execute the application by emulation of the computing device, wherein a graphic primitive function is invoked during the emulation at least one time, causing the workstation to present a graphic element on the display. The workstation is further adapted to delay execution of the application by a selected delay interval prior to each invocation of the graphic primitive function.

The invention provides a development system for testing a computing application for a resource-constrained mobile information device, including a display, and a workstation adapted to execute the application by emulation of the resource-constrained mobile information device, wherein double-buffering of graphic data that is presented on the display is enabled during the emulation, and the workstation is further capable of operation using a refresh rate that is selected to correspond to a refresh rate of the resource-constrained mobile information device.

According to another aspect of the development system, the refresh rate is further adjustable to correspond to a latency of a graphics API of the resource-constrained mobile information device.

The invention provides a method of emulating the performance of graphic operations of a resource constrained device, which is carried out by executing a computing application using an emulator of the device, inserting a delay prior to invocations of primitive graphic operations that are required by the computing application, disabling double buffering of a display of the emulator, and setting a refresh rate of the display to a predetermined value.

An additional aspect of the method includes determining whether the behavior of the computing application satisfied a predetermined testing criterion, and responsively to the determination, adjusting at least one of the delay and the refresh rate. The determination can be performed by observation of the display.

The invention provides a computer software product, including a computer-readable medium in which computer program instructions are stored, which instructions, when read by a computer, cause the computer to perform a method of emulating the performance of graphic operations of a resource constrained device, which is carried out by emulating an execution of a computing application on the device, inserting a delay prior to invocations of primitive graphic operations that are required by the computing application, disabling double buffering of a display of the computer, and setting a refresh rate of the display to a predetermined value.

### BRIEF DESCRIPTION OF THE DRAWINGS

For a better understanding of the present invention, reference is made to the detailed description of the invention, by way of example, which is to be read in conjunction with the following drawings, wherein:

FIG. 1 is a high level block diagram of a development system adapted to optimization of graphics performance on a target device, in accordance with a disclosed embodiment of the invention;

FIG. 2 is a flow chart illustrating a method of testing and optimizing an application intended to execute on a target device in accordance with a disclosed embodiment of the invention;

FIG. 3 is a detailed flow chart illustrating aspects of the method of FIG. 2 in further detail; and

FIG. 4 is a flow chart illustrating a method of testing and optimizing an application intended to execute on a target device in accordance with an alternate disclosed embodiment of the invention.

### DETAILED DESCRIPTION OF THE INVENTION

In the following description, numerous specific details are set forth in order to provide a thorough understanding of the present invention. It will be apparent to one skilled in the art, however, that the present invention may be practiced without these specific details. In other instances well-known circuits, control logic, and the details of computer program instructions for conventional algorithms and processes have not been shown in detail in order not to unnecessarily obscure the present invention.

Software programming code, which embodies aspects of the present invention, is typically maintained in permanent storage, such as a computer readable medium. In a client/server environment, such software programming code may be stored on a client or a server. The software programming code may be embodied on any of a variety of known media for use with a data processing system, This includes, but is not limited to, magnetic and optical storage devices such as disk drives, magnetic tape, compact discs (CD's), digital video discs (DVD's), and computer instruction signals embodied in a transmission medium with or without a carrier wave upon which the signals are modulated. For example, the transmission medium may include a communications network, such as the Internet.

Although the embodiments described in this patent application make use of particular features and vocabulary of the Java language and operating environments, and refer specifically to mobile device applications, the present invention is not limited to this context or to the particular implementation tools described here. Rather, the principles of the present invention may be applied using other programming languages, and may be used to solve problems of resource mismatches that may arise in development of applications for different sorts of target platforms.

Overview.

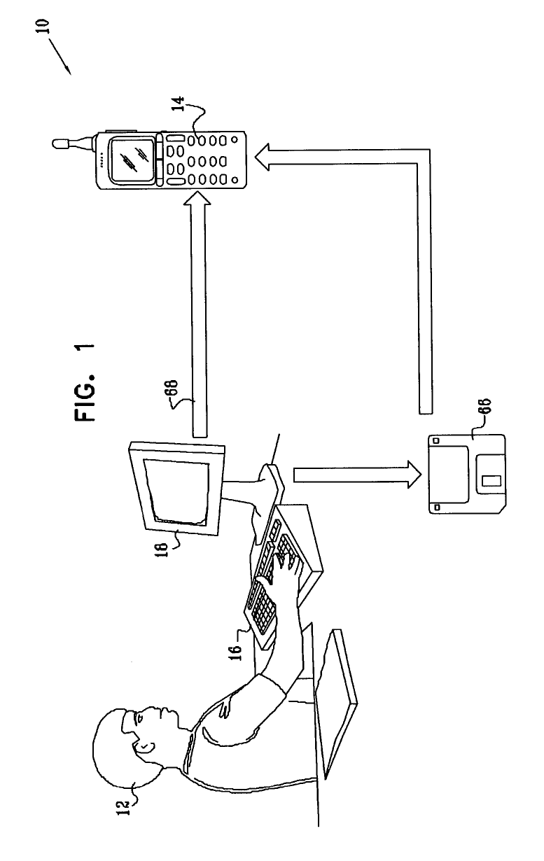

Reference is now made to FIG. 1, which is a high level block diagram of a system 10 that is adapted for development of an application or MIDlet for a target device in accordance with a disclosed embodiment of the invention. Typically, a developer 12 is attempting to create an application for a target device 14, which is typically, but not necessarily, a resource-constrained mobile information device. The target device 14 may be MIDP compliant, and can be a wireless device. Indeed, the system 10 can be applied to virtually any target device. Typically, development is done using an emulator 16, which can be realized as a system that includes a conventional workstation or personal computer, having appropriate emulation software installed, and provided with a display 18. An integrated development environment, for example the Sun ONE Studio, available from Sun Microsystems, Inc., can be installed on the workstation or computer in order to facilitate development of the application. The application is tested by executing the emulation software so as to emulate the target device 14.

The graphics performance of the hardware of the emulator 16 is generally far superior to that of the target device 14. Operations such as screen update and refresh, which are performed flawlessly in the development environment, sometimes prove to be disappointing in the field. The inventors have discovered that intentionally slowing the graphics system of the emulator 16 prevents such misleading results, and improves the quality of the application for the target device 14.

In one aspect of the invention, screen drawing speed, which is apparent to the user of the emulator 16 is reduced by the emulation software. This is accomplished in three ways:

First, the time to perform primitive graphic operations is increased. This timing change is user-configurable, and is adjusted to the requirements of a particular mobile information device.

Second, double-buffering of the emulated device is initially disabled, and may be subsequently re-enabled to evaluate its effect. The delay effected by disabling double-buffering is variable, depending on the processor speed and memory characteristics, and graphics display characteristics of the emulator 16. However, in combination with the other techniques disclosed herein, it has been found to be practical.

Third, the refresh rate of the display 18 is reset to a user-definable rate. This rate is generally less than the optimum refresh rate of the display 18. It is adjusted according to the characteristics of the target device 14, and the effectiveness of the other two techniques disclosed hereinabove.

In accordance with a disclosed embodiment of the invention, in a first mode of operation, delays are inserted immediately prior to invocations of graphic primitive functions. The pseudocode fragment of Listing 1 illustrates the technique.

### Listing 1

//The parameter t governs the delay interval

Delay (t);

CallGraphicsPrimitive( );

Advantageously in practice, double-buffering can be expressly disabled if the emulator 16 provides a built-in facility. In those systems that do not afford the user a capability of disabling double-buffering, the system screen refresh function can be called following invocations of graphic primitive functions. The pseudocode fragment of Listing 2 illustrates the technique.

### Listing 2

CallGraphicsPrimitive( );

Refresh( );

With continued reference to FIG. 1, in a second aspect of the present invention, double-buffering is expressly enabled. Delays are introduced by controlling the display refresh rate of the display 18, in order to emulate the display refresh rate and the latency of the graphics API in the target device 14.

The code fragments shown in Listing 3 and Listing 4 illustrates the technique of controlling the refresh rate of the display 18 by delay introduction, as further explained by the comments of the Listings. Because the speed of different graphics operations of the target device 14 may vary, it may be desirable to change the refresh rate of the display 18 dynamically during test runs of the application. The code assures that at least a user-specified interval occurs between successive invocations of the system's screen refresh function.

### Listing 3

//the parameters r1, r2 govern the refresh rate

SetRefreshRate (r1)

•

•

Program Steps

•

•

SetRefreshRate (r2)

•

•

Program Steps

•

•

### Listing 4

public class PeriodicDisplayUpdatePolicy {
Rectangle updateClip;
private int sleeptime;
public PeriodicDisplayUpdatePolicy( ) {
//Configurable refresh rate is set here
sleeptime = GetSleepTimeFromProperties( ) {
new Thread (new Runnable( ) {

public void run ( ) {
while (true) {

try {

Thread.sleep(sleepTime);
synchronized (updateClip) {
// REALLY REFRESH THE SCREEN
refresh(updateClip);

```
  // Notify that this refresh was
  // processed
  updateClip.notify( );
}
```

}

} catch (InterruptedException e) {

e.printStackTrace( );

}

}).start( );
// All REFRESH requests go to this method instead of
// calling refresh directly
public void updateDisplay (int x, int y, int width,

int height) {
synchronized (updateClip) {

updateClip.setBounds(x, y, width, height);
try {

// wait until this refresh request is
// processed, Processing
// speed is affected by the refresh rate
updateClip.wait( );

}catch (InterruptedException e) {

e.printStackTrace( );

}

}
}

}

Operation.

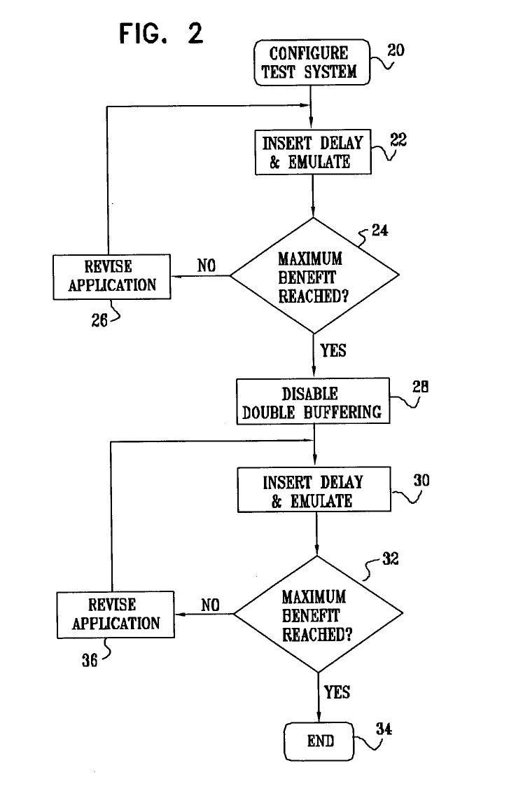

Reference is now made to FIG. 2, which is a flow chart illustrating a method of testing and optimizing an application intended to execute on a resource-constrained target device in accordance with the invention. The methods disclosed hereinbelow are by no means restricted to Java applications, MIDP applications, or applications for slow devices. Rather, the techniques are applicable to any graphic-intensive application on any platform. The sequence of applying the inventive techniques shown in FIG. 2 is exemplary, and it is possible to perform the steps in many different orders, as will occur to those skilled in the art. The process begins at initial step 20, wherein software is prepared. Here a developer identifies characteristics of the client, particularly its graphics capabilities and limitations. A development test system is configured to run the software by emulating the target device. The development test system can include a high performance workstation or personal computer.

Next, at step 22 a delay t₁ is inserted prior to calls of graphics primitive functions in the development test system that was configured in initial step 20. It is anticipated that the delay t₁ may need to be varied over a predefined range. Thus in some applications, the delay t₁ can be initially set at the midpoint of the predefined range, and adjusted according to emulation results. Alternatively, the delay t₁ can be initially set at one extreme end of the range, and systematically adjusted toward the other end of the range until satisfactory emulation results occur, or the range is exhausted. In some embodiments, satisfactory emulation is determined by direct observation of the display of the development test system. Test runs of the application are conducted in emulation mode using the development test system that was configured in initial step 20. Further details of step 22 are disclosed hereinbelow.

Next, at decision step 24, a determination is made whether step 22 resulted in maximum benefit in the emulation of the graphics functions of the target device. Typical evaluation criteria include, but are not limited to subjective and objective measurement of “smoothness” of graphics, absence of display flickering, and invisibility of intermediate or otherwise unnecessary graphics operations. Step 22 and decision step 24 are performed iteratively. Generally, in the first iteration it is not possible to determine if maximum benefit has been obtained, and the determination of decision step 24 is negative. In subsequent iterations, the performance of the present iteration is compared with that of the previous iteration. When an increment of performance determined in successive iterations falls below a predetermined minimum threshold, it is concluded that the process has converged to point of maximum benefit.

If the determination at decision step 24 is negative, then control proceeds to step 26. Here it is necessary to reevaluate the application under test, and to determine if coding changes are required to improve the display and otherwise optimize the code. After performance of step 26, control returns to step 22 to begin a new iteration.

If the determination at decision step 24 is affirmative, then yet another technique is applied. Control proceeds to step 28. Double buffering of the development test system's video display is disabled.

Control now passes to step 30, where the delay technique performed in the sequence beginning with step 22 is repeated. At step 30 a delay t₂ is again inserted prior to each call of a graphics primitive function in the development test system that was configured in initial step 20. Test runs of the application are conducted in emulation mode as in step 22, but with double buffering now disabled.

Next, at decision step 32, a determination is made whether this technique resulted in maximum benefit in emulating the graphics functions of the target device. Step 30 and decision step 32 are performed iteratively. Generally, in the first iteration it is not possible to determine if maximum benefit has been obtained, and the determination of decision step 32 is negative. In subsequent iterations, the performance of the present iteration is compared with that of the previous iteration. When an increment of performance determined in successive iterations falls below a predetermined minimum threshold, it is concluded that the process has converged to point of maximum benefit. Evaluation of graphics performance is done in the same manner as described above with reference to decision step 24. If the determination at decision step 32 is affirmative, then the procedure ends at final step 34.

If the determination at decision step 32 is negative, control proceeds to step 36. Here the application is re-evaluated. This is accomplished in the same manner as step 26. The details are not repeated. After performance of step 36, control returns to step 30 to begin a new iteration.

Reevaluation of the application at step 26 and step 36 at two different points in the evaluation and optimization process can expose rich opportunities for code optimization, as different graphic operations are observed directly, and under different conditions in the separate emulations of step 22 and step 30.

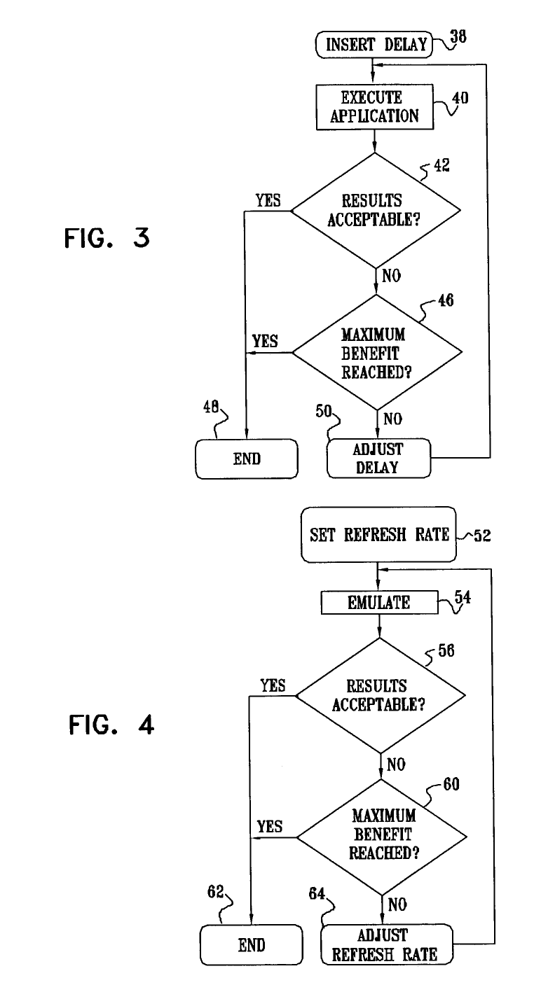

Reference is now made to FIG. 3, which is a flow chart illustrating step 22 (FIG. 2) in further detail as an iterative process. At initial step 38, a starting value for a delay t is introduced and is operative prior to each call of a graphics primitive of the development test system that was configured in initial step 20.

Next, at step 40, the application is emulated on the development test system, using the current value of the delay t.

Next, at decision step 42, a determination is made whether the performance of step 40 produced a satisfactory emulation, according to predetermined testing criteria, or in some applications, the subjective evaluation of the operator.

If the determination at decision step 42 is affirmative, then the procedure terminates at final step 48.

If the determination at decision step 42 is negative, then control proceeds to decision step 46. It is necessary to perform step 40 using different values of the delay t. A determination is now made whether maximum benefit has been achieved. This is accomplished by comparing the result of a present iteration with that of a previous iteration against a predetermined minimum performance criterion. If the determination at decision step 46 is affirmative, then control proceeds to final step 48.

If the determination at decision step 46 is negative, then control proceeds to step 50, where the value of the delay t is adjusted. Control returns to step 40, where the emulation is repeated using the new value of the delay t.

Reference is now made to FIG. 4, which is a flow chart illustrating step 30 (FIG. 2) as an iterative process in further detail. At initial step 52 an initial refresh rate is set.

Next, at step 54 the refresh rate of a display of the development test system is set, and emulation is performed as disclosed hereinabove. It is anticipated that the refresh rate may need to be varied over a predefined range. Thus in some applications, the refresh rate can be initially set at the midpoint of the predefined range, and adjusted according to emulation results. Alternatively, the refresh rate can be initially set at one extreme end of the range, and systematically adjusted toward the other end of the range until an optimum is determined, or the range is exhausted.

Next, at decision step 56, a determination is made whether step 54 resulted in satisfactory emulation of the graphics functions of the target device. Emulation may be adjudged as satisfactory if a threshold measure of performance is reached. Alternatively, an optimum performance may be required in order to consider the results as satisfactory. If the determination at decision step 56 is affirmative, then the procedure terminates at final step 62.

If the determination at decision step 56 is negative, then control proceeds to decision step 60. It is necessary to perform step 54 using different values of the refresh rate. A determination is now made whether maximum benefit has been achieved. This is accomplished by comparing the result of a present iteration with that of a previous iteration against a predetermined minimum criterion. If the determination at decision step 60 is affirmative, then control proceeds to final step 62.

If the determination at decision step 46 is negative, then control proceeds to step 64, where the value of the refresh rate is adjusted. Control returns to step 54, where emulation is repeated using the new refresh rate.

The techniques disclosed above with reference to FIG. 2, FIG. 3 and FIG. 4 can be performed concomitantly, or in many different sequences to obtain an optimal result. Furthermore, each of the techniques may be used individually, independently of the other techniques. It is often desirable that the delays used be much longer than those of the target device. Optimizing an application using such unrealistic delays guarantees that the application is optimally adapted to any real environment. Furthermore, testing the application using very long delays allow a developer to observe graphics operations individually, which will help him identify opportunities for improvement in the code.

Referring again to FIG. 1, after testing in emulation mode as disclosed herein, the application may be transferred to the target device 14 as a computer software product stored on a memory device 66, for example a ROM, that is adapted to the target device 14. Alternatively, the application can be downloaded to the target device 14 via a link 68. If desired, confirmatory testing of the application can then performed in the actual operating environment of the target device 14.

It will be appreciated by persons skilled in the art that the present invention is not limited to what has been particularly shown and described hereinabove. Rather, the scope of the present invention includes both combinations and sub-combinations of the various features described hereinabove, as well as variations and modifications thereof that are not in the prior art, which would occur to persons skilled in the art upon reading the foregoing description.

1. A method of testing a computing application for a computing device, comprising the step of:
executing said application on a workstation by an emulation of said computing device, said step of executing said application comprising the steps of:
invoking a graphic primitive function on said workstation at least one time; and
delaying execution of said graphic primitive function by a selected delay interval prior to each performance of said step of invoking a graphic primitive function.

2. The method according to claim 1, further comprising the steps of:
determining whether said emulation satisfied a predetermined testing criterion; and
responsively to said step of determining, adjusting said delay interval.

3. The method according to claim 1, further comprising the step of disabling double buffering of said workstation while executing said application.

4. The method according to claim 3, further comprising the steps of:
determining whether said emulation satisfied a predetermined testing criterion; and
responsively to said step of determining, adjusting said delay interval.

5. A method of testing a computing application for a computing device, comprising the steps of:
modifying a state of double-buffering of graphic data to be presented on a display of a workstation;
setting a refresh rate of said display to a predefined value; and
thereafter executing said application on said workstation by an emulation of said computing device.

6. The method according to claim 5, wherein said step of modifying a state of double-buffering is performed by enabling said double-buffering.

7. The method according to claim 5, further comprising the steps of:
determining whether said emulation satisfied a predetermined testing criterion; and
responsively to said step of determining, adjusting said refresh rate to a new value.

8. A computer software product, comprising a computer-readable medium in which computer program instructions are stored, which instructions, when read by a computer, cause the computer to perform a method of testing a computing application for a computing device, comprising the steps of:
executing said application on said computer by an emulation of said computing device, said step of executing said application comprising the steps of:
invoking a graphic primitive function on said computer at least one time; and
delaying execution of said graphic primitive function by a selected delay interval prior to each performance of said step of invoking a graphic primitive function.

9. The computer software product according to claim 8, wherein said computer is further instructed to perform the steps of:
determining whether said emulation satisfied a predetermined testing criterion; and
responsively to said step of determining, adjusting said delay interval.

10. The computer software product according to claim 8, wherein said computer is further instructed to perform the step of disabling double buffering of said computer while executing said application.

11. A computer software product, comprising a computer-readable medium in which computer program instructions are stored, which instructions, when read by a computer, cause the computer to perform a method of testing a computing application for a computing device, comprising the steps of:
modifying a state of double-buffering of graphic data to be presented on a display of said computer;
setting a refresh rate of said display to a predefined value; and
thereafter executing said application on said computer by an emulation of said computing device.

12. The computer software product according to claim 11, wherein said step of modifying a state of double-buffering is performed by enabling said double-buffering.

13. A development system for testing a computing application for a computing device, comprising:
a display; and
a workstation adapted to execute said application by emulation of said computing device, wherein a graphic primitive function is invoked during said emulation at least one time, causing said workstation to present a graphic element on said display, and said workstation is further adapted to delay execution of said application by a selected delay interval prior to each invocation of said graphic primitive function.

14. The development system according to claim 13, wherein double buffering of said graphic element on said display is modified during said emulation.

15. The development system according to claim 14, wherein said double buffering is enabled during said emulation.

16. A development system for testing a computing application for a resource-constrained mobile information device, comprising:
a display; and
a workstation adapted to execute said application by emulation of said resource-constrained mobile information device, wherein double-buffering of graphic data being presented on said display is enabled during said emulation, and said workstation is further capable of operation using a refresh rate that is selected to correspond to a refresh rate of said resource-constrained mobile information device.

17. The development system according to claim 16, wherein said refresh rate is further adjustable to correspond to a latency of a graphics API of said resource-constrained mobile information device.

18. A method of emulating the performance of graphic operations of a resource constrained device, comprising the steps of:
executing a computing application using an emulator of said device;
inserting a delay prior to invocations of primitive graphic operations that are required by said computing application;
disabling double buffering of a display of said emulator; and
setting a refresh rate of said display to a predetermined value.

19. The method according to claim 18, further comprising the steps of:
determining whether a behavior of said computing application satisfied a predetermined testing criterion; and
responsively to said step of determining, adjusting at least one of said delay and said refresh rate.

20. The method according to claim 19, wherein said step of determining is performed by observation of said display.

21. A computer software product, comprising a computer-readable medium in which computer program instructions are stored, which instructions, when read by a computer, cause the computer to perform a method of emulating the performance of graphic operations of a resource constrained device, comprising the steps of:
emulating an execution of a computing application on said device;
inserting a delay prior to invocations of primitive graphic operations that are required by said computing application;
disabling double buffering of a display of said computer; and
setting a refresh rate of said display to a predetermined value.

22. The computer software product according to claim 21, further comprising the steps of:
determining whether a behavior of said computing application satisfied a predetermined testing criterion; and
responsively to said step of determining, adjusting at least one of said delay and said refresh rate.

23. The computer software product according to claim 22, wherein said step of determining is performed by observation of said display.
